(19) United States
(12) Patent Application Publication
(10) Pub. No.: US 2011/0193126 A1
(43) Pub. Date: Aug. 11, 2011

(54) SEMICONDUCTOR LIGHT-EMITTING ELEMENT AND METHOD FOR MANUFACTURING THE SAME

(75) Inventors: Takafumi Oka, Tokyo (JP); Shinji Abe, Tokyo (JP); Kazushige Kawasaki, Tokyo (JP); Hitoshi Sakuma, Tokyo (JP)

(73) Assignee: MITSUBISHI ELECTRIC CORPORATION, Tokyo (JP)

(21) Appl. No.: 12/911,772

(22) Filed: Oct. 26, 2010

(30) Foreign Application Priority Data
Feb. 9, 2010 (JP) 2010-026592

(51) Int. Cl. H01L 33/40; H01L 21/283

(52) U.S. Cl. 257/99; 438/39; 257/E33.063; 257/E21.202

(57) ABSTRACT

A semiconductor light-emitting element comprises: a semiconductor substrate; a semiconductor laminated structure including a first conductivity-type semiconductor layer, an active layer, a second conductivity-type semiconductor layer, and a contact layer that are sequentially laminated on the semiconductor substrate; a ridge portion in an upper portion of the semiconductor laminated structure; a channel portion adjoining opposite sides of the ridge portion; a terrace portion adjoining opposite sides of the channel portion and, with the channel portion, sandwiching the ridge portion; a first insulating film covering the channel portion and having openings on the ridge portion and the terrace portion; a single-layer adhesive layer on the first insulating film; a Pd electrode on the ridge portion and a part of the single-layer adhesive layer and electrically connected to the contact layer of the ridge portion; and a second insulating layer covering a portion not covered by the Pd electrode of the single-layer adhesive layer, and the terrace portion.

### BACKGROUND OF THE INVENTION

1. Field of the Invention

The present invention relates to a semiconductor light-emitting element preventing the peel-off of the Pd electrode and reducing the stress of the adhesive layer, and a method for manufacturing such a semiconductor light-emitting element highly accurately.

2. Background Art

In a semiconductor light-emitting element having a ridge portion, an electric power is applied to an active layer when a voltage is applied to the contact layer on the top of the ridge portion. For the power supply, a p-type electrode is formed on the contact layer. Due to the requirement of higher outputs and lower consumption currents and the like, a low-resistance ohmic electrode is used as the p-type electrode contacting the contact layer. In addition, from the viewpoint of the yield and reliability of the semiconductor light-emitting element, it is required that the materials for electrode are strongly adhered to the base material and are not peel off during the processes.

When a blue-violet laser is manufactured using a nitride semiconductor such as GaN, if Ni is used as the material of the p-type electrode, electrical properties such as ohmic properties cannot be improved. Therefore, a Pd electrode composed of Pd (or a Pd-based material) is often used as the p-type electrode. The Pd electrode becomes a low-resistance ohmic electrode to a nitride semiconductor such as GaN (for example, refer to Japanese Patent Application Laid-Open No. 2009-129973 (Paragraph 0002)).

Since it is difficult to form the Pd electrode so as to contact only the contact layer in the ridge portion because of reasons such as process capacity, the Pd electrode also contact the insulating film. However, since the adhesion of the pa electrode and the insulating film is low, the exfoliation of the Pd electrode occurs. Although the exfoliation of the Pd electrode may occur anytime after forming the Pd electrode, it will especially easily occur after sintering heat treatment.

To prevent the exfoliation of the Pd electrode, an adhesive layer is formed between the Pd electrode and the insulating film.

As a technique for forming the adhesive layer, the use of a degenerated semiconductor such as ITO (Indium-Tin-Oxides), a platinum-based metal and/or the oxide thereof has been proposed (for example, refer to Japanese Patent Application Laid-Open No. 2005-51137 (Paragraphs 0014 to 0016, FIG. 1) and Japanese Patent Application Laid-Open No. 2006-128622 (Paragraphs 0020 to 0022, FIG. 1)).

However, in conventional adhesive layers, the force to adhere the Pd electrode and the insulating film was still weak, causing a problem of the partial exfoliation of the Pd electrode. Therefore, the present inventors proposed a semiconductor light-emitting element using a multi-layer adhesive layer wherein a plurality of metal layers are laminated (for example, refer to Japanese Patent Application Laid-Open No. 2009-176900 (Claim 1, Paragraph 0016, FIG. 1)).

### SUMMARY OF THE INVENTION

In the multi-layer adhesive layer wherein a plurality of metal layers are laminated, stress is generated. In addition, in the ridge-type semiconductor light-emitting element, a double-channel structure having channel portions pinching the ridge portion from the both sides, and a terrace portion located outside of the respective channel portions may be adopted. The multi-layer adhesive layer in Japanese Patent Application Laid-Open No. 2009-176900 (Claim 1, Paragraph 0016, FIG. 1) coated not only the channel portions but also the terrace portion, and had a large area. Therefore, a problem, wherein the stress of the multi-layer adhesive layer was large, was caused.

For manufacturing the semiconductor light-emitting element in Japanese Patent Application Laid-Open No. 2009-176900 (Claim 1, Paragraph 0016, FIG. 1), it was required to form a resist only on the top of the ridge portion. However, it was difficult to form the resist only on the top of the ridge portion without inter-product fluctuation due to the capacity of manufacturing equipment.

In view of the above-described problems, an object of the present invention is to provide a semiconductor light-emitting element preventing the peel-off of the Pd electrode and reducing the stress of the adhesive layer, and a method for manufacturing such a semiconductor light-emitting element highly accurately.

According to one aspect of the present invention, a semiconductor light-emitting element comprises: a semiconductor substrate; a semiconductor laminated structure including a first conductivity-type semiconductor layer, an active layer, a second conductivity-type semiconductor layer, and a contact layer that are sequentially laminated on the semiconductor substrate; a ridge portion in an upper portion of the semiconductor laminated structure; a channel portion adjoining the ridge portion; a terrace portion adjoining the channel portion and pinching the channel portion with the ridge portion; a first insulating film coating the channel portion and having openings on the ridge portion and the terrace portion; a single-layer adhesive layer on the first insulating film; a Pd electrode coating the ridge portion and a part of the single-layer adhesive layer and connected to the contact layer of the ridge portion; and a second insulating layer coating a portion not coated with the Pd electrode of the single-layer adhesive layer and the terrace portion.

According to another aspect of the present invention, a method for manufacturing a semiconductor light-emitting element comprising: sequentially laminating a first conductivity-type semiconductor layer, an active layer, a second conductivity-type semiconductor layer, and a contact layer on a semiconductor substrate in order to form a semiconductor laminated structure; forming a resist on the semiconductor laminated structure; etching the semiconductor laminated structure using the resist as a mask in order to form a ridge portion in an upper portion of the semiconductor laminated structure; sequentially forming a first insulating film and a single-layer adhesive layer on the resist and the semiconductor laminated structure; carrying out liftoff for removing the first insulating film and the single-layer adhesive layer on the resist with the resist; and after the liftoff, forming a Pd electrode coating the ridge portion and a part of the single-layer adhesive layer and connected to the contact layer of the ridge portion.

The present invention makes it possible to provide a semiconductor light-emitting element preventing the peel-off of the Pd electrode and reducing the stress of the adhesive layer, and a method for manufacturing such a semiconductor light-emitting element highly accurately.

Other and further objects, features and advantages of the invention will appear more fully from the following description.

### BRIEF DESCRIPTION OF THE DRAWINGS

FIG. 1 is a sectional view showing a semiconductor light-emitting element according to the embodiment of the present invention.

FIGS. 2 to 11 are sectional views for illustrating the method for manufacturing a semiconductor light-emitting element according to an embodiment of the present invention.

FIG. 12 is a sectional view showing a modified example of semiconductor light-emitting element according to an embodiment of the present invention.

### DETAILED DESCRIPTION OF THE PREFERRED EMBODIMENTS

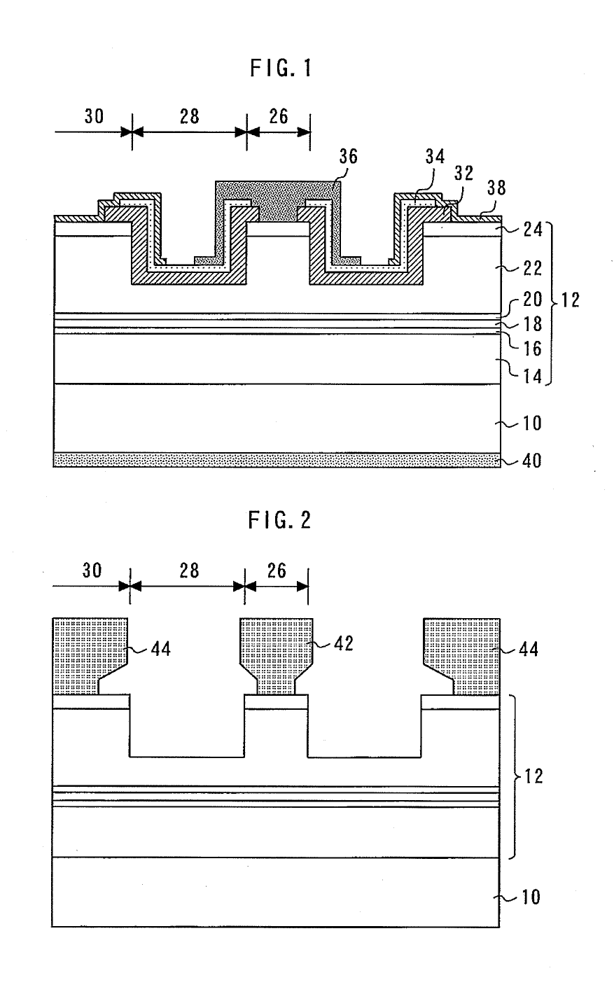

A semiconductor light-emitting element according to an embodiment of the present invention will be described referring to the drawings. FIG. 1 is a sectional view showing a semiconductor light-emitting element according to the embodiment of the present invention. The semiconductor light-emitting element is a nitride semiconductor laser having a double-channel structure.

A semiconductor laminated structure 12 that constitutes a resonator structure is formed on an n-type GaN substrate 10 (semiconductor substrate). The semiconductor laminated structure 12 includes an n-type AlGaN clad 14 (first conductivity-type semiconductor layer), an n-type GaN guide layer 16 (first conductivity-type semiconductor layer), an MQW-InGaN active layer 18 (active layer), a p-type GaN guide layer 20 (second conductivity-type semiconductor layer), a p-type AlGaN clad layer 22 (second conductivity-type semiconductor layer), and a p-type GaN contact layer 24 (contact layer) that are sequentially laminated on the n-type GaN substrate 10.

A ridge portion 26 is formed as a current-narrowing structure in the upper portion of the semiconductor laminated structure 12. The ridge portion 26 is a stripe-shaped elevated portion. A channel portion 28 adjoins the ridge portion 26 and pinches the ridge portion 26 from the both sides. The channel portion 28 is formed to be lower than the ridge portion 26. The width of the channel portion 28 is about 10 μm. A terrace portion 30 adjoins the channel portion 28 and pinches the channel portion 28 with the ridge portion. The terrace portion 30 is an elevated portion formed to be higher than the channel portion 28. The channel portion 28 forms a channel portion between the terrace portion 30 and the ridge portion 26. Such a structure is referred to as a double-channel structure, and excels in the uniformity in wafer processing, and wire-bonding properties and die-bonding properties in assembling.

A first insulating film 32 composed of SiO₂ coats the channel portion 28. The first insulating film 32 has openings on the ridge portion 26 and the terrace portion 30. A single-layer adhesive layer 34 having a film thickness of 30 nm is formed on the first insulating film 32. The single-layer adhesive layer 34 is a Ti layer or a Cr layer. The single-layer adhesive layer 34 is formed not only on the first insulating film 32 of the channel portion 28, but also on the first insulating film 32 extending to the end portions of the ridge portion 26 and the terrace portion 30.

A Pd electrode 36 coats the ridge portion 26 and a part of the single-layer adhesive layer 34. The Pd electrode 36 is integrally formed so as to contact the p-type GaN contact layer 24 in the ridge portion 26 and to contact the single-layer adhesive layer 34 in the channel portion 28. The Pd electrode 36 is electrically connected to the p-type GaN contact layer 24 in the ridge portion 26 so as to supply electricity to the MQW-InGaN active layer 18. The Pd electrode 36 is not formed in the entire channel portion 28, but formed from the ridge portion 26 to the vicinity of the ridge portion 26 and the terrace portion 30, and does not overlap a second insulating film 38 formed on the single-layer adhesive layer 34 in the channel portion 28.

A second insulating film 38 composed of SiO₂ coats the portion not coated with the Pd electrode 36 of the single-layer adhesive layer 34 in the channel portion 28 and the semiconductor laminated structure 12 in the terrace portion 30. An n electrode 40 is formed on the back face of the n-type GaN substrate 10. The n electrode 40 has a Ti film contacting the n-type GaN substrate 10, and an Au film laminated thereon.

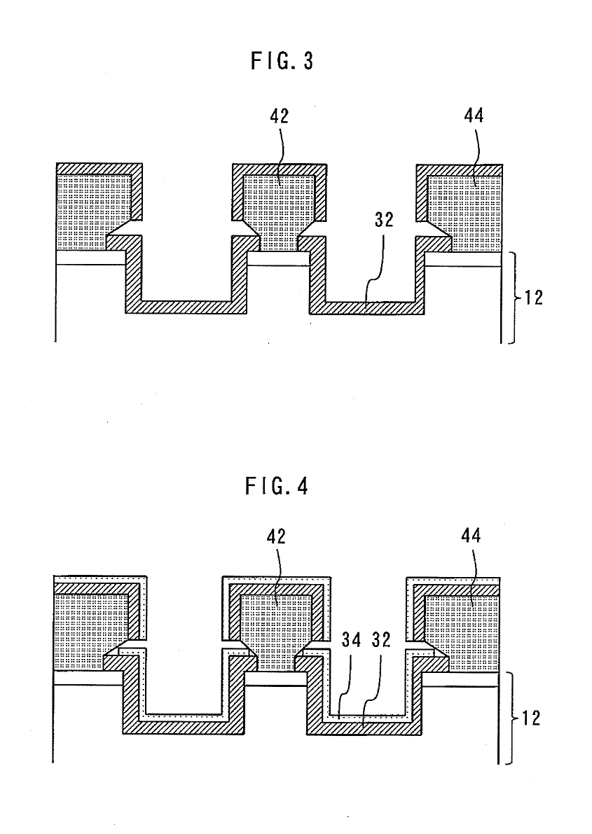

Next, a method for manufacturing a semiconductor light-emitting element according to an embodiment of the present invention will be described referring to the drawings. FIGS. 2 to 11 are sectional views for illustrating the method for manufacturing a semiconductor light-emitting element according to an embodiment of the present invention. In FIGS. 3 to 11, portions below the semiconductor laminated structure 12 will be omitted.

First, as shown in FIG. 2, a semiconductor laminated structure 12 on an n-type GaN substrate 10 is formed. Next, a first resist 42 located on a region for forming a ridge portion 26 and a second resist 44 located outside the first resist are formed by photolithography on the semiconductor laminated structure 12. The semiconductor laminated structure 12 is etched using the first and second resists 42 and 44 as masks to form a ridge portion 26 and a terrace portion 30 above the semiconductor laminated structure 12, respectively. The first resist 42 is disposed on the ridge portion 26, and the second resist 44 is disposed on the terrace portion 30.

Next, as shown in FIG. 3, a first insulating film 32 is formed on the first and second resists 42, 44 and the semiconductor laminated structure 12. Then, as shown in FIG. 4, a single-layer adhesive layer 34 is formed on the first insulating film 32 by vapor deposition or sputtering. The first insulating film 32 and the single-layer adhesive layer 34 are formed so as to coat the channel portion 28. The single-layer adhesive layer 34 can be accurately disposed on the first insulating film 32 without newly using photolithography or the like.

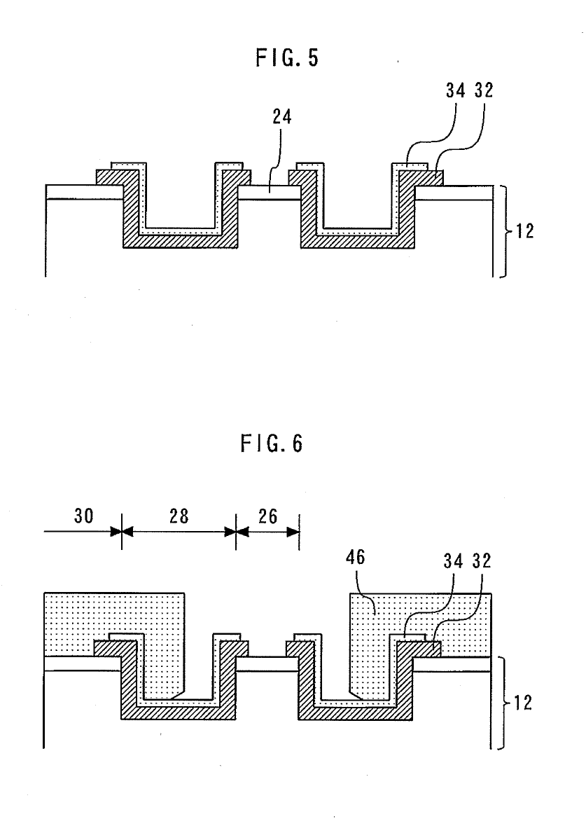

Next, as shown in FIG. 5, the first insulating film 32 and the single-layer adhesive layer 34 on the first and second resists 42 and 44 are subjected to liftoff to remove them with the first and second resist 42 and 44. When liftoff is carried out, the p-type GaN contact layer 24 is exposed at the ridge portion 26 and the terrace portion 30.

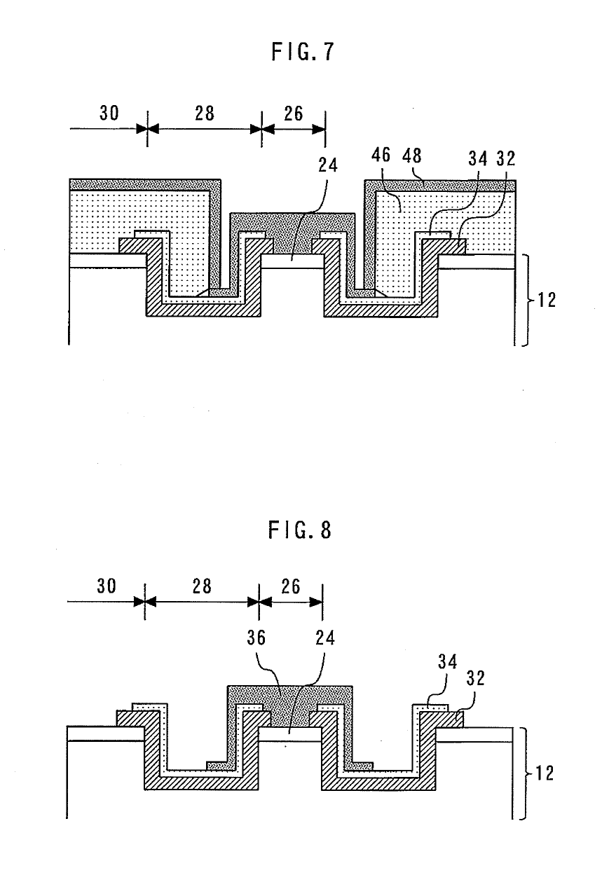

Next, as shown in FIG. 6, a resist 46 is formed using photolithography so as to coat the terrace portion 30 and the sidewall of the channel portion 28 on the terrace portion 30 side. Then, as shown in FIG. 7, a Pd layer 48 is formed on the entire surface of the wafer using vapor deposition. Here, the Pd layer 48 contacts the p-type GaN contact layer 24 in the ridge portion 26; contacts the single-layer adhesive layer 34 in the channel portion 28 on the ridge portion 26 side; contacts the resist 46 on the terrace portion 30 side; and contacts the resist 46 in the terrace portion 30.

Next, as shown in FIG. 8, liftoff for removing the Pd layer 48 on the resist 46 together with the resist 46 is carried out. Thereby, a Pd electrode 36 that coats the ridge portion 26 and a part of the single-layer adhesive layer 34 is formed. The Pd electrode 36 is electrically connected to the p-type GaN contact layer 24 in the ridge portion 26; and contacts the single-layer adhesive layer 34 on the sidewall of the ridge portion 26 side, and on the channel bottom in the channel portion 28.

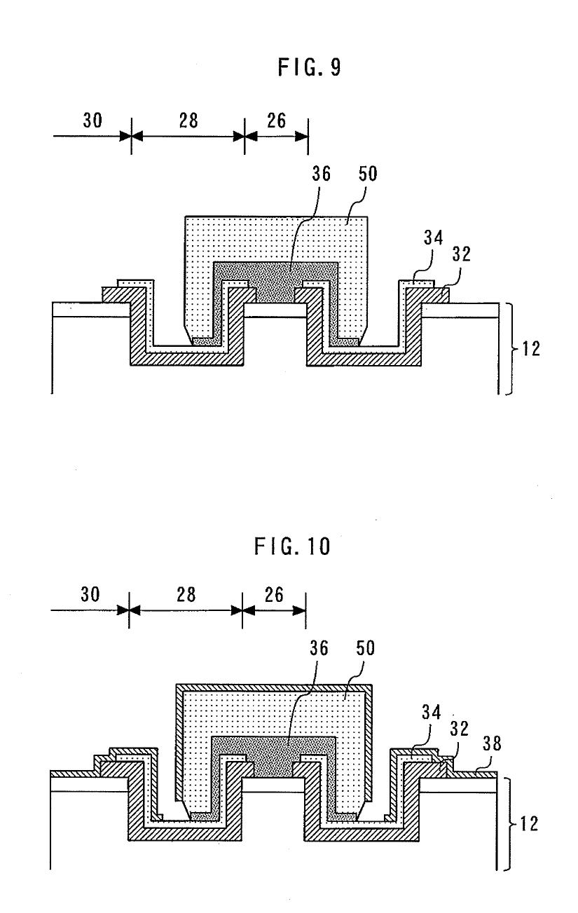

Next, as shown in FIG. 9, a resist 50 that coats the Pd electrode 36 in the ridge portion 26 and the channel portion 28 is formed using photolithography. Then, as shown in FIG. 10, a second insulating film 38 is formed on the entire surface of the wafer. The second insulating film 38 is present on the resist 50 in the ridge portion 26; on the resist 50 and the single-layer adhesive layer 34 in the channel portion 28; and on the semiconductor laminated structure 12 in the terrace portion 30.

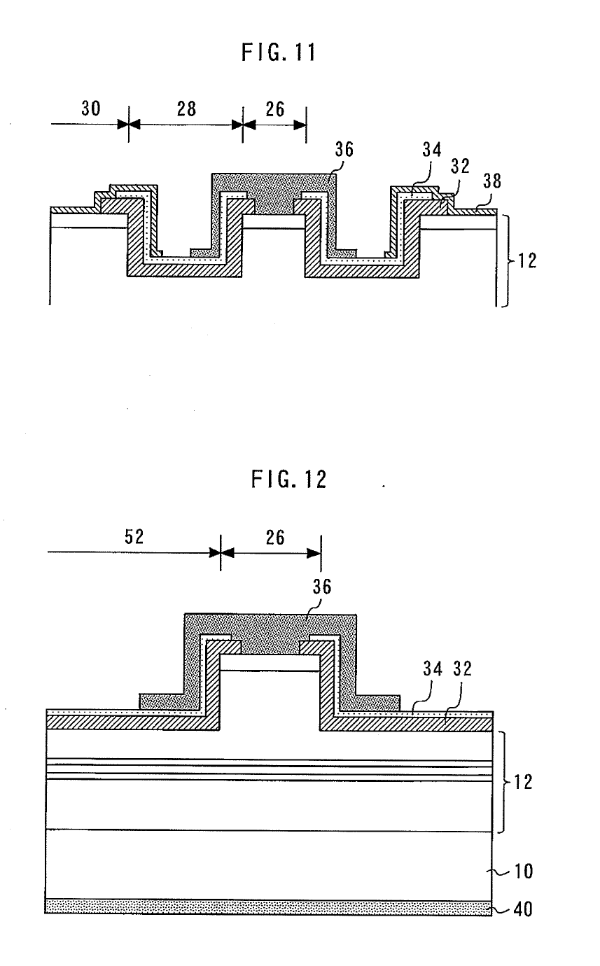

Next, as shown in FIG. 11, liftoff for removing the second insulating film 38 on the resist 50 together with the resist 50 is carried out. The remaining second insulating film 38 coats the portion of the single-layer adhesive layer 34 not coated with the Pd electrode 36, and the terrace portion 30; and does not contact the Pd electrode 36.

After the Pd electrode 36 has been formed, sintering heat treatment is carried out at a temperature of about 400 to 550° C. By the sintering heat treatment, the ohmic contact of the Pd electrode 36 and the p-type GaN contact layer 24 can be achieved in the ridge portion 26, and adhesion is further elevated. An n electrode 40 is also formed on the back face of the n-type GaN substrate 10. By the above-described processes, the semiconductor light-emitting element according to the present embodiment is manufactured.

In the semiconductor light-emitting element according to the present embodiment, the single-layer adhesive layer 34 is present between the Pd electrode 36 and the first insulating film 32. An alloy is formed in the interface between the single-layer adhesive layer 34 and the Pd electrode 36, and the adhesion of the Pd electrode 36 and the first insulating film 32 is elevated. Therefore, the peel-off of the Pd electrode 36 can be prevented. Although the single-layer adhesive layer 34 contacts the second insulating film 38, their adhesion is also favorable.

By using the single-layer adhesive layer 34 as the adhesive layer, the stress of the adhesive layer can be reduced compared with a multi-layer adhesive layer. Furthermore, since the single-layer adhesive layer 34 does not coat the terrace portion 30 to reduce the area of the adhesive layer, the stress of the adhesive layer can be further lowered.

Also by using the single-layer adhesive layer 34 as the adhesive layer, no shape abnormality or the like of the adhesive layer occurs during liftoff, the precision of the shapes of the adhesive layer and the Pd electrode are favorable. Especially, since a plurality of layers must be formed in narrow channel regions in the case of a double-channel structure, the effect is profound.

In semiconductor light-emitting elements, the temperature of portions other than end surfaces may elevate during operations. If the temperature of the element elevates to a certain temperature or higher, the occurrence of the deterioration of characteristics or the loss of reliability may be considered. However, in the semiconductor light-emitting element according to the present embodiment, since the single-layer adhesive layer is formed of a metal and heat dissipation characteristics is favorable, such problems of deterioration or the like can be suppressed.

In addition, in the method for manufacturing the semiconductor light-emitting element according to the present embodiment, the first and the second resists 42 and 44 used for forming the ridge portion 26 and the terrace portion 30 are inverted for the patterning of the first insulating film 32 and the single-layer adhesive layer 34. Thereby, it is not required to form the resist only on the top of the ridge portion like conventional techniques, and the semiconductor light-emitting element can be highly accurately manufactured.

Although the semiconductor light-emitting element according to the present embodiment, has a double-channel structure, the present embodiment is not limited thereto, but the terrace portion 30 is not always required. FIG. 12 is a sectional view showing a modified example of semiconductor light-emitting element according to an embodiment of the present invention. In this modified example, the terrace portion 30 is not present, and the ridge portion 26 and the non-ridge portion 52 are formed above the semiconductor laminated structure 12. Since the single-layer adhesive layer 34 is present between the Pd electrode 36 and the first insulating film 32, the peel-off of the Pd electrode can be prevented. Also by using the single-layer adhesive layer 34, the stress of the adhesive layer can be lowered compared with the multi-layer adhesive layer.

In the present embodiment, although the Pd electrode 36 is a Pd single layer, the present invention is not limited thereto, but may have a structure wherein other materials are laminated on the Pd layer that contacts the p-type GaN contact layer 24. For example, a two-layer structure including a Pd layer and a Ta layer laminated on the Pd layer, or a three-layer structure including a Pd layer, a Ta layer, and a Pd layer which are sequentially laminated may also be used, and another layer made of a different material may be further laminated on top of these. In the case of a Pd/Ta two-layer structure, it has been confirmed from the experimental results that the contact resistance can be lowered than a Pd single layer. Specifically, when the Pd electrode 36 was changed from the Pd single layer to the Pd/Ta two-layer structure in the structure shown in FIG. 1, the contact resistivity was single-digit or double-digit lowered. In the case of a Pd/Ta/Pd three-layer structure, the oxidation of the Ta surface can also be prevented.

In the present embodiment, although the first and second insulating films 32 and 38 are composed of SiO₂, the present invention is not limited thereto, but SiN, SiON, TEOS (Tetraethyl Orthosilicate), ZrO₂, TiO₂, Ta₂O₅, Al₂O₃, Nb₂O₅, Hf₂O₅, or AlN may also be used. Also in the present embodiment, although the film thickness of the single-layer adhesive layer 34 is 30 nm, the present invention is not limited thereto, but it can be optionally determined taking required adhesion or the like in consideration.

Although the present embodiment was described when the present invention was applied to a nitride semiconductor laser, the present invention can also be applied to semiconductor lasers or LEDs or the like using other materials such as GaAs if they are semiconductor light-emitting elements using Pd electrodes.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2010-026592, filed on Feb. 9, 2010 including specification, claims, drawings and summary, on which the Convention priority of the present application is based, are incorporated herein by reference in its entirety.

1. A semiconductor light-emitting element comprising:
a semiconductor substrate;
a semiconductor laminated structure including a first conductivity-type semiconductor layer, an active layer, a second conductivity-type semiconductor layer, and a contact layer that are sequentially laminated on the semiconductor substrate;
a ridge portion in an upper portion of the semiconductor laminated structure;
a channel portion adjoining opposite sides of the ridge portion;
a terrace portion adjoining opposite sides of the channel portion and, with the channel portion, sandwiching the ridge portion;
a first insulating film coating the channel portion and having openings on the ridge portion and the terrace portion;
a single-layer adhesive layer on the first insulating film;
a Pd electrode covering the ridge portion and a part of the single-layer adhesive layer and electrically connected to the contact layer of the ridge portion; and
a second insulating layer covering a portion of the single-layer adhesive layer not covered by the Pd electrode, and the terrace portion.

2. The semiconductor light-emitting element according to claim 1, wherein the single-layer adhesive layer is one of Ti and Cr.

3. The semiconductor light-emitting element according to claim 1, wherein the Pd electrode includes a two-layer structure including a Pd layer and a Ta layer laminated on the Pd layer.

4. A method for manufacturing a semiconductor light-emitting element comprising:
sequentially laminating a first conductivity-type semiconductor layer, an active layer, a second conductivity-type semiconductor layer, and a contact layer on a semiconductor substrate, in this order, to form a semiconductor laminated structure;
forming a resist pattern on the semiconductor laminated structure;
etching the semiconductor laminated structure using the resist pattern as a mask and forming a ridge portion in an upper portion of the semiconductor laminated structure;
sequentially forming a first insulating film and a single-layer adhesive layer on the resist pattern and on the semiconductor laminated structure;
lifting off the resist pattern and removing the first insulating film and the single-layer adhesive layer on the resist pattern, with the resist pattern; and
after the lifting off, forming a Pd electrode covering the ridge portion and a part of the single-layer adhesive layer and electrically connected to the contact layer of the ridge portion.

5. The method for manufacturing a semiconductor light-emitting element according to claim 4, further comprising:
forming the resist pattern to include a first resist pattern located on a region for forming the ridge portion and a second resist pattern located outside the first resist pattern;
etching the semiconductor laminated structure using the first and second resist patterns as masks in order to form, respectively, the ridge portion and the terrace portion in the upper portion of the semiconductor laminated structure; and
forming a second insulating layer covering a portion not covered by the Pd electrode of the single-layer adhesive layer, and the terrace portion.

6. The method for manufacturing a semiconductor light-emitting element according to claim 4, wherein the single-layer adhesive layer is one of Ti and Cr.

7. The method for manufacturing a semiconductor light-emitting element according to claim 4, including forming the Pd electrode as a two-layer structure including sequentially laminating a Pd layer and a Ta layer on the Pd layer.

8. The method for manufacturing a semiconductor light-emitting element according to claim 4, including sintering after forming the Pd electrode.

9. The semiconductor light-emitting element according to claim 1, wherein the Pd electrode includes a three-layer structure including a Pd layer, a Ta layer, and a Pd layer which are sequentially laminated.

10. The method for manufacturing a semiconductor light-emitting element according to claim 4, including forming the Pd electrode as a three-layer structure by sequentially laminating a Pd layer, a Ta layer, and a Pd layer.
